(19) United States
(12) Patent Application Publication
(10) Pub. No.: US 2018/0197960 A1
(43) Pub. Date: Jul. 12, 2018

(54) TFT array substrate, manufacturing method thereof, and liquid crystal display apparatus

(71) Applicant: Shenzhen China Star Optoelectronics Technology Co., Ltd., Shenzhen, Guangdong (CN)

(72) Inventor: Xiaowen LV, Shenzhen, Guangdong (CN)

(73) Assignee: Shenzhen China Star Optoelectronics Technology Co., Ltd., Shenzhen, Guangdong (CN)

(21) Appl. No.: 15/123,776

(22) PCT Filed: Jul. 20, 2016
(86) PCT No.: PCT/CN2016/090586

§ 371 Date: Sep. 6, 2016

(30) Foreign Application Priority Data
Jun. 21, 2016 (CN) 2016104577888

(51) Int. Cl. H01L 29/417; H01L 27/12; H01L 29/16; H01L 29/786; H01L 29/24; G02F 1/1368; H01L 29/66

(52) U.S. Cl. CPC H01L 29/41733; G02F 2202/10; H01L 29/1604; H01L 29/78669; H01L 27/1225; H01L 29/24; H01L 29/7869; H01L 29/78618; H01L 29/78696; H01L 27/127; G02F 1/1368; H01L 29/66765; H01L 29/66969; G02F 2202/103; H01L 27/1222

(57) ABSTRACT

The present disclosure discloses a TFT array substrate, a manufacturing method thereof and a liquid crystal display apparatus. The TFT array substrate comprising: a substrate; and a TFT disposed on the substrate; the TFT comprises a semiconductor layer and both a source electrode and a drain electrode disposed on the semiconductor layer, and wherein a contact surface between the semiconductor layer and the source electrode and/or a contact surface between the semiconductor layer and the drain electrode are uneven structure. Through above manner, the present disclosure can reduce contact resistance between the semiconductor layer and the metal layer and can improve electrical characteristic of TFT apparatus.

### TECHNICAL FIELD

The disclosure is related to display technology field, and in particular to a TFT array substrate, a manufacturing method thereof and a liquid crystal display apparatus.

### DESCRIPTION OF RELATED ART

TFT is the abbreviation of Thin Film Transistor. With TFT technology, each liquid crystal pixel point on a liquid crystal display is driven by a thin film transistor integrated behind the pixel point, hence information on a screen can be displayed with high speed, high brightness and a high contrast ratio.

During the manufacturing process of TFT, the process of the contact interface between metal layer where M2 is (source electrode/drain electrode) and A-Si (amorphous silicon) is still a very important part, because potential difference is existed between metal and A-Si to form schottky contact easily. However, TFT device needs electrical contact, and the contact should be a low resistance instead of rectification. Therefore, semiconductor should be doped to form an ohmic contacting with M2 and A-Si. Even through A-Si is doped by p-type, the resistance between metal and semiconductor is still large.

### BRIEF SUMMARY

A technical problem mainly solved in the present disclosure is to provide a TFT array substrate, manufacturing method thereof and a liquid crystal display apparatus to decrease contract resistance between a semiconductor layer and a metal layer, and to improve electrical characteristic of TFT apparatus.

To solve the above technical problem, the disclosure applies a technical solution is: a TFT array substrate is provided; wherein the TFT array substrate comprises a substrate and a TFT disposed on the substrate, and the TFT array substrate comprises a gate electrode, a gate insulating layer, a semiconductor layer and a source-drain layer sequentially disposed on the substrate; wherein the source-drain layer comprises a source electrode and a drain electrode; wherein the source electrode and the drain electrode are made of metal, and wherein a contact surface between the semiconductor layer and the source electrode and/or a contact surface between the semiconductor layer and the drain electrode are uneven structure.

Wherein the contact surface between the semiconductor layer and the source electrode and the contact surface between the semiconductor layer and the drain electrode comprise a plurality of intersecting grooves.

Wherein the intersecting grooves comprise a plurality of grooves extended in first direction and a plurality of grooves extended in second direction, and the grooves extended in first direction and the grooves extended in second direction are crisscross.

Wherein the contact surface between the semiconductor layer and the source electrode and the contact surface between the semiconductor layer and the drain electrode comprise a plurality of disjoint concave holes.

Wherein the semiconductor layer is a doped A-Si layer.

Wherein the semiconductor layer is Indium Gallium Zinc Oxide (IGZO).

To solve above technical problem, the disclosure applies another technical solution is: a manufacturing method for TFT array substrate is provided; the manufacturing method comprises: a substrate is provided; a gate electrode, a gate insulating layer, a semiconductor layer and a source-drain layer sequentially are formed on the substrate; a uneven structure is manufactured on a upper surface of the semiconductor layer; a source electrode and a drain electrode are formed on the semiconductor layer.

Wherein the step of manufacturing the uneven structure on the upper surface of the semiconductor layer comprises: the uneven structure is formed on the upper surface of the semiconductor layer through imprinting, laser machining or photolithography.

To solve above technical problem, the disclosure applies another technical solution is: a liquid crystal display apparatus is provided; the liquid crystal display apparatus comprises a display panel and a backlight; the display panel comprises a TFT array substrate, a color film substrate and a liquid crystal layer disposed between the TFT array substrate and the color film substrate; wherein the TFT array substrate comprises a substrate and a TFT disposed on the substrate; wherein the TFT array substrate comprises a semiconductor layer and both a source electrode and a drain electrode disposed on the semiconductor layer; wherein a contact surface between the semiconductor layer and the source electrode and/or a contact surface between the semiconductor layer and the drain electrode are uneven structure.

Wherein the contact surface between the semiconductor layer and the source electrode and the contact surface between the semiconductor layer and the drain electrode comprise a plurality of intersecting grooves.

Wherein the intersected intersecting grooves comprise a plurality of grooves extended in first direction and a plurality of grooves extended in second direction, and wherein the grooves extended in first direction and the grooves extended in second direction are crisscross.

Wherein the contact surface between the semiconductor layer and the source electrode and the contact surface between the semiconductor layer and the drain electrode comprise a plurality of disjoint concave holes.

Wherein the semiconductor layer is a doped A-Si layer.

Wherein the semiconductor layer is Indium Gallium Zinc Oxide (IGZO).

Wherein the TFT array substrate comprises a gate electrode, a gate insulating layer, a semiconductor layer and a source-drain layer sequentially disposed on the substrate, and wherein the source-drain layer comprises a source electrode and a drain electrode.

The advantage of the disclosure is: to distinguish the differences from the related art, the TFT array substrate of the disclosure comprises a substrate and a TFT disposed on the substrate; the TFT array substrate comprises a semiconductor layer and both a source electrode and a drain electrode disposed on the semiconductor layer; wherein a contact surface between the semiconductor layer and the source electrode and/or a contact surface between the semiconductor layer and the drain electrode are uneven structure; Through above manner, contact areas between the semiconductor layer and a metal layer (source-drain layer) can be reduced, and distance between the metal layer and channel is also reduced. Thus contact resistance between the semiconductor layer and the metal layer will be reduced, schottky barrier on surface of semiconductor will be reduced, and electrical characteristic of TFT apparatus will be improved.

### BRIEF DESCRIPTION OF THE DRAWINGS

FIG. 1 is a schematic structural view of a preferred embodiment of a TFT array substrate according to the disclosure.

FIG. 2 is a side view for a contact surface between a semiconductor layer and a source-drain layer of a preferred embodiment of the TFT array substrate according to the disclosure.

FIG. 3 is a plan view of a semiconductor layer of a preferred embodiment of the TFT array substrate according to the disclosure.

FIG. 4 is another plan view of a semiconductor layer of a preferred embodiment of the TFT array substrate according to the disclosure.

FIG. 5 is another plan view of a semiconductor layer of a preferred embodiment of the TFT array substrate according to the disclosure.

FIG. 6 is a flowchart diagram of a preferred embodiment of a manufacturing method for the TFT array substrate according to the present disclosure.

FIG. 7 is a schematic structural view of a preferred embodiment of liquid crystal display apparatus according to the disclosure.

### DETAILED DESCRIPTION

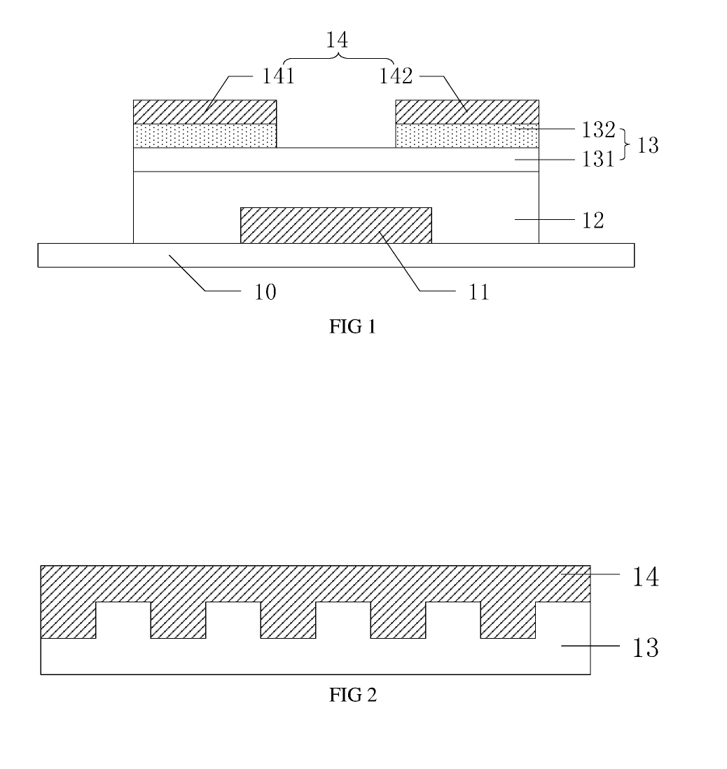

Referring to FIG. 1, FIG. 1 is a schematic structural view of a preferred embodiment of a TFT array substrate according to the disclosure. The TFT array substrate comprises a substrate 10 and a TFT disposed on the substrate 10.

Wherein the TFT comprises a gate electrode 11, a gate insulating layer 12, a semiconductor layer 13 and a source-drain layer 14 sequentially disposed on the substrate 10, and wherein the source-drain layer 14 comprises a source electrode 141 and a drain electrode 142.

Alternately, the substrate 10 can be either glass substrate or plastic substrate.

Alternately, the gate electrode 11 and the source-drain layer 14 can be metal layer.

Alternately, the gate insulating layer 12 can be either SiOx or SiNx, and can be mixture of SiOx and SiNx; further, the gate insulating layer 12 can comprise a layer of SiOx and a layer of SiNx.

Alternately, the semiconductor layer 13 can be one of A-Si, P-Si and LTPS, and can be doped semiconductor of A-Si, P-Si and LTPS as well. For example, the semiconductor layer 13 comprises a A-Si 131 and N+ doped region or P+ doped region formed on the A-Si 131 (132 is marked in FIG. 1.)

Alternately, the semiconductor layer 13 can be also Indium Gallium Zinc Oxide (IGZO).

Specifically, the TFT array substrate comprises a semiconductor layer 13 and both a source electrode 141 and a drain electrode 142 disposed on the semiconductor layer 13, and wherein a contact surface between the semiconductor layer 13 and the source electrode 141 and/or a contact surface between the semiconductor layer 13 and the drain electrode 142 are uneven structure.

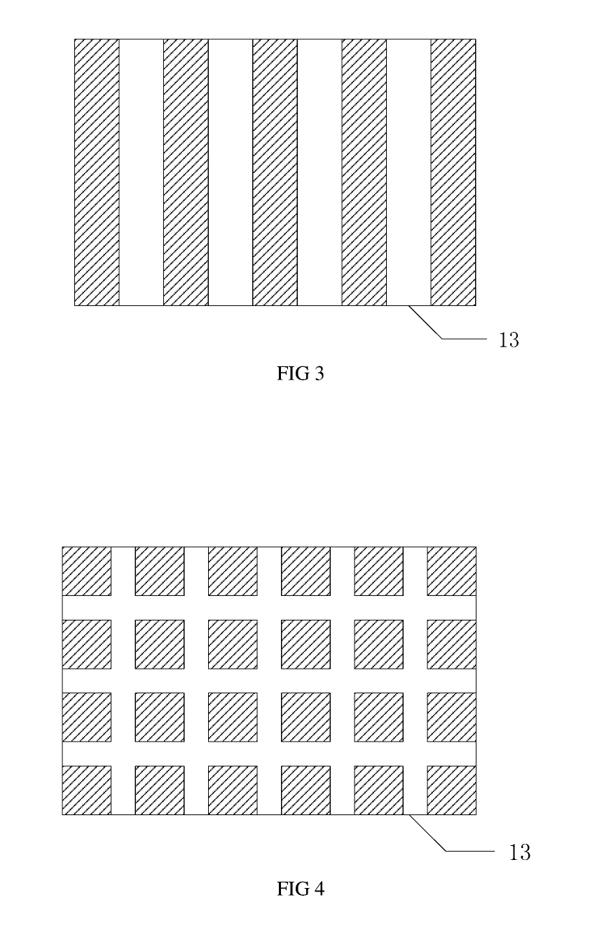

Specifically referring to FIG. 2 and FIG. 3, FIG. 2 is a side view for a contact surface between a semiconductor layer and a source-drain layer of a preferred embodiment of the TFT array substrate according to the disclosure, and FIG. 3 is a plan view of a semiconductor layer of a preferred embodiment of the TFT array substrate according to the disclosure; in FIG. 3, shading portions show protrusions, and blank portions show grooves.

The schottky contact is the contact between a semiconductor layer 13 and a source-drain layer 14; the schottky contact means that when metal material and semiconductor material contact to each other, the contact interface of the semiconductor can be bended to form schottky contact barrier; a large interface resistance is existing from the existence of schottky contact barrier to make the electrical characteristic getting worse. Although the doping processed on the semiconductor layer 13 can improve the electrical characteristic of the TFT, the efficiency is not good enough.

In the embodiment, because an upper surface of the semiconductor layer 13 is uneven structure, contact areas is enlarged; therefore the contact resistance between the source-drain layer 14 and the semiconductor layer 13 can be decreased.

As shown in FIG. 4, FIG. 4 is another plan view of a semiconductor layer of a preferred embodiment of the TFT array substrate according to the disclosure, wherein protrusions are shown in the shading portions, and grooves are shown at the blank portions.

Wherein a contact surface between the semiconductor layer 13 and the source electrode and a contact surface between the semiconductor layer 13 and the drain electrode comprise a plurality of intersecting grooves.

Alternately, a plurality of intersecting grooves comprise a plurality of grooves extended in first direction and a plurality of grooves extended in second direction, and the grooves extended in first direction and the grooves extended in second direction are crisscross.

Alternately, the first direction can be perpendicular to the second direction as shown in FIG. 4; in another embodiment, an angle between the first direction and the second direction can be between 0-90°, and the first direction can be the direction of a certain angle with a frame of the display panel.

The grooves comprise two crisscross direction of grooves, and numbers of the grooves can be increased so that the contact areas of the semiconductor layer and source-drain layer can be more increased.

As shown in FIG. 5, FIG. 5 is another plan view of a semiconductor layer of a preferred embodiment of the TFT array substrate according to the disclosure, wherein shading portions show protrusions, and blank portions show grooves.

Wherein the contact surface between the semiconductor layer 13 and the source electrode and the contact surface between the semiconductor layer 13 and the drain electrode comprise a plurality of disjoint concave holes.

An upper surface of the semiconductor layer 13 comprises a plurality of concave holes so that contact areas between the semiconductor layer and the source-drain layer.

Besides, it could be understood that in another embodiment, the array substrate can further comprise pixel electrodes, common electrodes, and etc.

Distinguish over the prior art, the TFT array substrate in the embodiment comprises a substrate and a TFT disposed on the substrate; the TFT comprises a semiconductor layer and a source electrode a drain electrode disposed on TFT. Wherein a contact surface between the semiconductor layer and the source electrode and/or a contact surface between the semiconductor layer and the drain electrode are uneven structure. Through above manner, contact areas between the semiconductor layer and a metal layer (source-drain layer) can be reduced, and distance between the metal layer and channel is also reduced. Thus contact resistance between the semiconductor layer and the metal layer will be reduced, schottky barrier on surface of semiconductor will be reduced, and electrical characteristic of TFT apparatus will be improved.

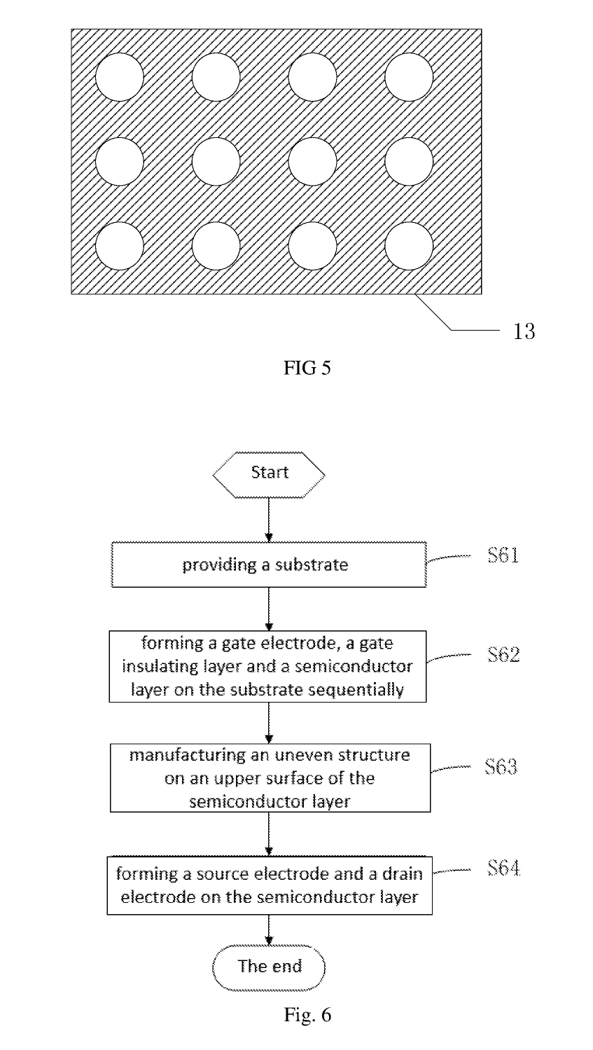

Referring to FIG. 6, FIG. 6 is a flowchart diagram of a preferred embodiment of a manufacturing method for the TFT array substrate according to the present disclosure, the method comprises:

S61: providing a substrate.

Alternately, the substrate can be either transparent glass substrate or plastic substrate.

S62: a gate electrode, a gate insulating layer and a semiconductor layer sequentially are formed on the substrate.

Wherein method of forming the gate electrode, the gate insulating layer and the semiconductor layer sequentially on the substrate are generally used on physical vapor deposition or chemical vapor deposition.

Alternately, in another embodiment, the process of forming the semiconductor layer can specifically comprise:

Depositing A-Si, and performing N+ doped or P+ doped on A-Si;

or depositing A-Si, and performing excimer laser annealing process on A-Si to form polysilicon (P-Si). Wherein P-Si comprises both low temperature poly-Silicon (LTPS) and high temperature poly-Silicon (HTPS).

S63: manufacturing an uneven structure on an upper surface of the semiconductor layer.

Wherein the step S63 can specifically be that: manufacturing the uneven structure on the upper surface of the semiconductor layer through imprinting, laser machining or photolithography.

S64: forming a source electrode and a drain electrode on the semiconductor layer.

The method of forming the source electrode and the drain electrode on the semiconductor layer is that: depositing a layer of metal on the semiconductor layer; therefore, metal is filled in the uneven structure on the semiconductor layer to enlarge the contact area between the semiconductor and the metal.

In addition, it is understood that, in other embodiments, pixel electrodes, common electrodes and etc. can further be formed on the TFT after S64.

Distinguish over the prior art, the manufacturing method of TFT array substrate in the embodiment comprises: providing a substrate; forming a gate electrode, a gate insulating layer and a semiconductor layer on the substrate sequentially; manufacturing a uneven structure on a upper surface of the semiconductor layer; forming a source electrode and a drain electrode on the semiconductor layer. Through above manner, contact areas between the semiconductor layer and a metal layer (source-drain layer) can be reduced, and distance between the metal layer and channel is also reduced. Thus contact resistance between the semiconductor layer and the metal layer will be reduced, schottky barrier on surface of semiconductor will be reduced, and electrical characteristic of TFT apparatus will be improved.

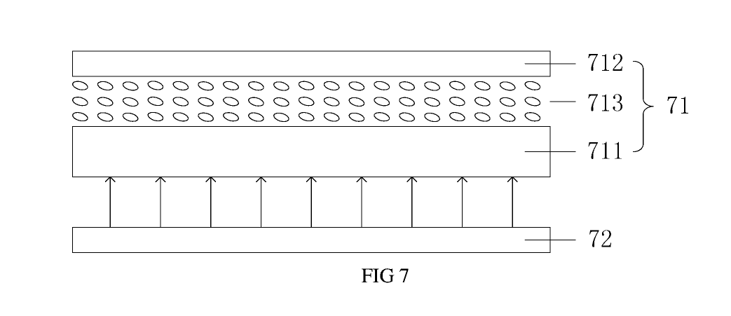

Referring to FIG. 7, FIG. 7 is a schematic structural view of a preferred embodiment of liquid crystal display apparatus according to the disclosure. The liquid crystal display apparatus comprises a display panel 71 and a backlight 72, and the display panel 71 comprises a TFT array substrate 711, a color film substrate 712 and a liquid crystal layer 713 disposed between the TFT array substrate and the color film substrate; the TFT comprises a semiconductor layer and a source electrode a drain electrode disposed on TFT; Wherein a contact surface between the semiconductor layer and the source electrode and/or a contact surface between the semiconductor layer and the drain electrode are uneven structure.

Particularly, the array substrate 711 is as the array substrate described above in every embodiment, and the structure, manufacturing method and practicing principle or steps can be refer to the above descriptions, thus no further description thereof here.

Even though information and the advantages of the present embodiments have been set forth in the foregoing description, together with details of the mechanisms and functions of the present embodiments, the disclosure is illustrative only; and that changes may be made in detail, especially in matters of shape, size and arrangement of parts within the principles of the present embodiments to the full extend indicated by the broad general meaning of the terms in which the appended claims are expressed.

1. A TFT array substrate, the TFT array substrate comprising: a substrate; and a TFT disposed on the substrate;
the TFT comprises a gate electrode, a gate insulating layer, a semiconductor layer and a source-drain layer sequentially disposed on the substrate, wherein the source-drain layer comprises a source electrode and a drain electrode,
wherein the source electrode and the drain electrode are made of metal, and
wherein a contact surface between the semiconductor layer and the source electrode and/or a contact surface between the semiconductor layer and the drain electrode are uneven structure.

2. The TFT array substrate according to claim 1, wherein the contact surface between the semiconductor layer and the source electrode and the contact surface between the semiconductor layer and the drain electrode comprise a plurality of intersecting grooves.

3. The TFT array substrate according to claim 2, wherein the intersecting grooves comprise a plurality of grooves extended in first direction and a plurality of grooves extended in second direction, and the grooves extended in first direction and the grooves extended in second direction are crisscross.

4. The TFT array substrate according to claim 1, wherein the contact surface between the semiconductor layer and the source electrode and the contact surface between the semiconductor layer and the drain electrode comprise a plurality of disjoint concave holes.

5. The TFT array substrate according to claim 1, wherein the semiconductor layer is a doped amorphous silicon layer.

6. The TFT array substrate according to claim 1, wherein the semiconductor layer is Indium Gallium Zinc Oxide (IGZO).

7. A method for manufacturing TFT array substrate, the method comprising:
providing a substrate;
forming a gate electrode, a gate insulating layer and a semiconductor layer on the substrate sequentially;
manufacturing an uneven structure on an upper surface of the semiconductor layer;
forming a source electrode and a drain electrode on the semiconductor layer.

8. The method according to claim 7, wherein the step of manufacturing the uneven structure on the upper surface of the semiconductor layer comprises:
manufacturing the uneven structure on the upper surface of the semiconductor layer through imprinting, laser machining or photolithography.

9. A liquid crystal display apparatus, the liquid crystal display apparatus comprising: a display panel, and a backlight, wherein the display panel comprises a TFT array substrate, a color film substrate and a liquid crystal layer disposed between the TFT array substrate and the color film substrate,
wherein the TFT array substrate comprises a substrate and a TFT disposed on the substrate,
wherein the TFT comprises a semiconductor layer and both a source electrode and a drain electrode disposed on the semiconductor layer, and wherein a contact surface between the semiconductor layer and the source electrode and/or a contact surface between the semiconductor layer and the drain electrode are uneven structure.

10. The liquid crystal display apparatus according to claim 9, wherein the contact surface between the semiconductor layer and the source electrode and the contact surface between the semiconductor layer and the drain electrode comprise a plurality of intersecting grooves.

11. The liquid crystal display apparatus according to claim 10, wherein the intersected intersecting grooves comprise a plurality of grooves extended in first direction and a plurality of grooves extended in second direction, and wherein the grooves extended in first direction and the grooves extended in second direction are crisscross.

12. The liquid crystal display apparatus according to claim 9, wherein the contact surface between the semiconductor layer and the source electrode and the contact surface between the semiconductor layer and the drain electrode comprise a plurality of disjoint concave holes.

13. The liquid crystal display apparatus according to claim 9, wherein the semiconductor layer is a doped amorphous silicon layer.

14. The liquid crystal display apparatus according to claim 9, wherein the semiconductor layer is Indium Gallium Zinc Oxide (IGZO).

15. The liquid crystal display apparatus according to claim 9, wherein the TFT comprises a gate electrode, a gate insulating layer, a semiconductor layer and a source-drain layer sequentially disposed on the substrate, wherein the source-drain layer comprises a source electrode and a drain electrode.
